(19) United States
(12) Patent Application Publication
(10) Pub. No.: US 2026/0215177 A1
(43) Pub. Date: Jul. 23, 2026

(54) FILM FORMATION METHOD AND PROCESSING SYSTEM

(71) Applicant: Tokyo Electron Limited, Tokyo (JP)

(72) Inventors: Osamu YOKOYAMA, Yamanashi (JP); Toshiaki ARIMA, Yamanashi (JP); Atsushi MATSUMOTO, Yamanashi (JP)

(21) Appl. No.: 19/431,249

(22) Filed: Dec. 23, 2025

(30) Foreign Application Priority Data
Jan. 23, 2025 (JP) 2025-009619

(51) Int. Cl. H10P 14/40; H01J 37/32; H10P 14/43

(52) U.S. Cl. CPC H10P 14/414; H01J 37/3244; H10P 14/43; H01J 2237/332

(57) ABSTRACT

A technique for improving the concentration of an n-type impurity contained in a diffusion-preventing layer present between a substrate and a metal silicide film is provided. A film formation method according to one embodiment of the present disclosure includes: (a) preparing a substrate having a doped region containing silicon and an n-type impurity on a surface of the substrate; (b) supplying a first metal-containing gas to form an adsorption-promoting layer on the doped region; (c) supplying an n-type impurity-containing gas containing the n-type impurity to form a diffusion-preventing layer containing the n-type impurity on the adsorption-promoting layer; and (d) supplying a second metal-containing gas to form a first metal film over the doped region over which the diffusion-preventing layer is formed, and to form a first metal silicide film through reaction between the first metal film and the silicon in the doped region.

### CROSS-REFERENCE TO RELATED APPLICATION

The present application claims priority under 35 U.S.C. § 119 to Japanese Patent Application No. 2025-009619, filed Jan. 23, 2025, the contents of which are incorporated herein by reference in their entireties.

### BACKGROUND OF THE INVENTION

### Field of the Invention

The present disclosure relates to a film formation method and a processing system.

### Description of the Related Art

Techniques of supplying a titanium-containing gas to a silicon wafer, forming a plasma to form a titanium film, and forming a titanium silicide film through reaction between the titanium film and silicon of the silicon wafer are known. (for example, see Japanese Patent Application Laid-Open Publication No. 2004-158828 and Japanese Patent Application Laid-Open Publication No. 2003-203976).

### SUMMARY OF THE INVENTION

A film formation method according to one embodiment of the present disclosure includes: (a) preparing a substrate having a doped region containing silicon and an n-type impurity on a surface of the substrate; (b) supplying a first metal-containing gas to form an adsorption-promoting layer on the doped region; (c) supplying an n-type impurity-containing gas containing the n-type impurity to form a diffusion-preventing layer containing the n-type impurity on the adsorption-promoting layer; and (d) supplying a second metal-containing gas to form a first metal film over the doped region over which the diffusion-preventing layer is formed, and to form a first metal silicide film through a reaction between the first metal film and the silicon in the doped region.

### BRIEF DESCRIPTION OF THE DRAWINGS

FIG. 1 is a flowchart showing an example of a film formation method according to a first embodiment;

FIG. 2A is a cross-sectional view showing an example of the film formation method according to the first embodiment;

FIG. 2B is a cross-sectional view showing the example of the film formation method according to the first embodiment;

FIG. 2C is a cross-sectional view showing the example of the film formation method according to the first embodiment;

FIG. 2D is a cross-sectional view showing the example of the film formation method according to the first embodiment;

FIG. 2E is a cross-sectional view showing the example of the film formation method according to the first embodiment;

FIG. 3 is a flowchart showing an example of a film formation method according to a second embodiment;

FIG. 4A is a cross-sectional view showing an example of the film formation method according to the second embodiment;

FIG. 4B is a cross-sectional view showing the example of the film formation method according to the second embodiment;

FIG. 4C is a cross-sectional view showing the example of the film formation method according to the second embodiment;

FIG. 4D is a cross-sectional view showing the example of the film formation method according to the second embodiment;

FIG. 4E is a cross-sectional view showing the example of the film formation method according to the second embodiment;

FIG. 5 is a view showing an example of a processing system according to an embodiment;

FIG. 6 is a view showing an example of a processing apparatus according to an embodiment;

FIG. 7 is a graph showing measurement results of the concentration of an n-type impurity contained in a diffusion-preventing layer in each of Example 1 and Comparative Examples 1 and 2;

FIG. 8 is a graph showing measurement results of the concentration of an n-type impurity contained in a diffusion-preventing layer in each of Example 2, Example 3, and Comparative Example 3; and

FIG. 9 is a graph showing measurement results of the concentration of an n-type impurity contained in a diffusion-preventing layer, with respect to changes in a processing pressure at which a diffusion-preventing layer is formed.

### DETAILED DESCRIPTION OF THE DISCLOSURE

Non-limiting exemplary embodiments of the present disclosure will be described below with reference to the accompanying drawings. In all of the accompanying drawings, the same or corresponding members or components are denoted by the same or corresponding reference numerals, and redundant descriptions thereof will be omitted.

### Film Formation Method According to First Embodiment

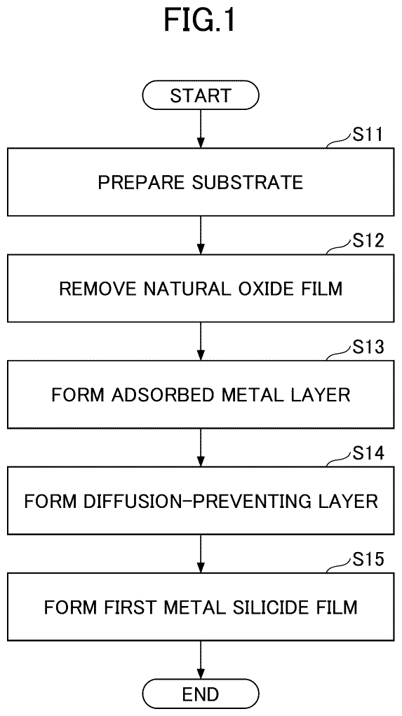

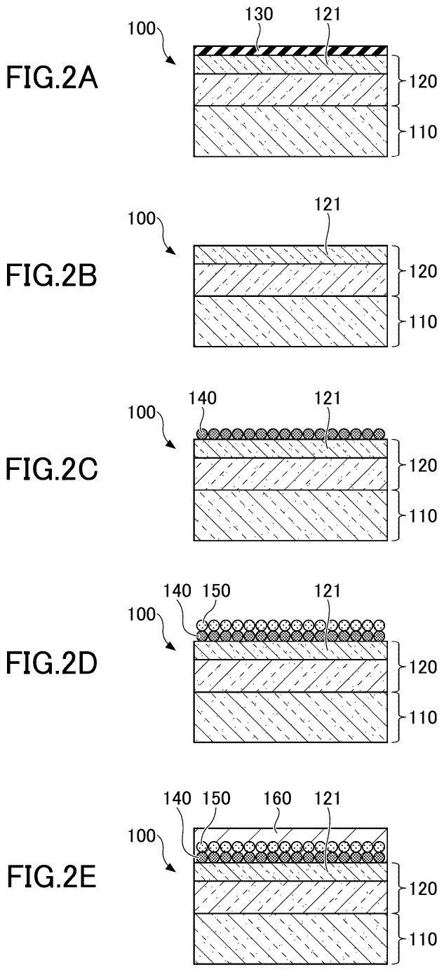

Referring to FIGS. 1 and 2, an example of a film formation method according to the first embodiment will be described. FIG. 1 is a flowchart showing an example of the film formation method according to the first embodiment. FIGS. 2A to 2E are cross-sectional views showing an example of the film formation method according to the first embodiment.

The film formation method according to the first embodiment includes steps S11 to S15 shown in FIG. 1. Step S11 includes preparing a substrate 100 having a doped region 121 containing silicon (Si) and an n-type impurity on a surface of the substrate 100. Step S11 may include, for example, loading the substrate 100 into a processing vessel.

As shown in FIG. 2A, the substrate 100 includes a single crystal substrate 110 and an epitaxial layer 120 on the single crystal substrate 110. Each of the single crystal substrate 110 and the epitaxial layer 120 contains silicon (Si). In the example shown in FIG. 2A, the doped region 121 constitutes a surface of the epitaxial layer 120. The doped region 121 is, for example, a region exposed from a contact hole formed in an insulating film.

The n-type impurity contained in the doped region 121 is, for example, phosphorus (P). However, the n-type impurity is not limited to phosphorus. Other examples of the n-type impurity contained in the doped region 121 include arsenic (As) and antimony (Sb). As shown in FIG. 2A, a natural oxide film 130, such as silicon oxide and the like, might be present on a surface of the doped region 121.

Step S12 is performed after step S11. As shown in FIG. 2B, step S12 includes removing the natural oxide film 130 present on the surface of the doped region 121. However, when there is no natural oxide film 130 on the surface of the doped region 121, step S12 can be omitted.

Step S12 includes, for example, performing a Chemical Oxide Removal (COR) treatment and a Post Heat Treatment (PHT) in this order. The COR treatment is a treatment for supplying a gas containing a halogen element and a basic gas to the substrate 100 as processing gases to cause a chemical reaction between the natural oxide film 130 present on the surface of the doped region 121 and the processing gases to produce a reaction product. The gas containing a halogen element is, for example, hydrogen fluoride (HF) gas. The basic gas is, for example, ammonia (NH₃) gas. In this case, a reaction product mainly containing ammonium silicofluoride [(NH₄)₂SiF₆] and water (H₂O) is generated. The PHT is a treatment for heating the reaction product produced from the COR treatment to sublimate the reaction product, such as ammonium silicofluoride or the like. However, step S12 is not limited to performing the COR treatment and the PHT in this order. For example, in step S12, the PHT may be omitted.

Step S13 is performed after step S12. As shown in FIG. 2C, step S13 includes supplying a first metal-containing gas to form an adsorbed metal layer 140 as an adsorption-promoting layer on the doped region 121. The adsorption-promoting layer promotes adsorption of an n-type impurity of a diffusion-preventing layer 150 containing the n-type impurity to be formed in step S14. In step S13, for example, metal-containing molecules in the first metal-containing gas may be physically adsorbed or chemically adsorbed to the doped region 121. By the metal-containing molecules in the first metal-containing gas adsorbing to the doped region 121, the adsorbed metal layer 140 is formed.

The metal contained in the first metal-containing gas is, for example, titanium (Ti). Examples of the first metal-containing gas containing titanium include titanium tetrachloride (TiCl₄) gas, titanium bromide (TiBr₄) gas, dimethylamino titanium (TDMAT) gas, and diethylamino titanium (TDEAT) gas. However, the metal contained in the first metal-containing gas is not limited to titanium. Examples of other metals that may be contained in the first metal-containing gas include nickel (Ni), molybdenum (Mo), tantalum (Ta), hafnium (Hf), zirconium (Zr), ruthenium (Ru), niobium (Nb), antimony (Sb), and bismuth (Bi). Examples of the first metal-containing gas containing nickel include tetracarbonylnickel (Ni(CO)₄). Examples of the first metal-containing gas containing molybdenum include molybdenum pentachloride (MoCl₅), molybdenum oxytetrachloride (MoOCl₄), and molybdenum dichlorodioxide (MoO₂Cl₂). Examples of the first metal-containing gas containing tantalum include tantalum pentachloride (TaCl₅) and tantalum pentafluoride (TaF₅). Examples of the first metal-containing gas containing hafnium include hafnium tetrachloride (HfCl₄) and hafnium tetrafluoride (HfF₄). Examples of the first metal-containing gas containing zirconium include zirconium tetrachloride (ZrCl₄). Examples of the first metal-containing gas containing ruthenium include dodecacarbonyl triruthenium (Ru₃CO₁₂). Examples of the first metal-containing gas containing niobium include niobium pentachloride (NbCl₅) and niobium pentafluoride (NbF₅). Examples of the first metal-containing gas containing antimony include antimony trichloride (SbCl₃), antimony pentachloride (SbCl₅), antimony pentafluoride (SbF₅), antimony tribromide (SbBr₃), and antimony triiodide (SbI₃). Examples of the first metal-containing gas containing bismuth include bismuth trichloride (BiCl₃), bismuth tribromide (BiBr₃), and bismuth triiodide (BiI₃).

Step S13 may include supplying a carrier gas together with the first metal-containing gas. The carrier gas is, for example, an inert gas, such as nitrogen (N₂) gas, argon (Ar) gas, and the like.

In step S13, it is preferable to maintain the temperature of the substrate 100 at 400° C. or higher and 480° C. or lower. The first metal-containing gas contains a metal and has a property of easily adsorbing to the doped region 121. Therefore, even if the temperature of the substrate 100 in step S13 is a relatively low temperature of approximately 400° C., molecules in the first metal-containing gas that have reached the doped region 121 can be kept to the doped region 121. Thus, even if the temperature of the substrate 100 is a relatively low temperature of approximately 400° C., it is possible to secure the adsorbed metal layer 140 on the doped region 121 in a substantial amount. On the other hand, if the temperature of the substrate 100 in step S13 exceeds, for example, 480° C., there is an increased possibility that the substrate 100 is deteriorated by heat and various characteristics of the substrate 100 are impaired. Therefore, by setting the temperature of the substrate 100 in step S13 to 400° C. or higher and 480° C. or lower, it is possible to avoid deterioration of the substrate 100 and to secure the adsorbed metal layer 140 on the doped region 121 in a substantial amount. However, the temperature of the substrate 100 in step S13 is not limited to 400° C. or higher and 480° C. or lower. The temperature of the substrate 100 in step S13 may be appropriately set depending on the types and the like of the first metal-containing gas and the substrate 100.

In step S13, the first metal-containing gas is supplied without being formed into a plasma. By supplying the first metal-containing gas without forming it into a plasma, it is possible to avoid damage to the doped region 121 which might otherwise be caused by ions in a plasma.

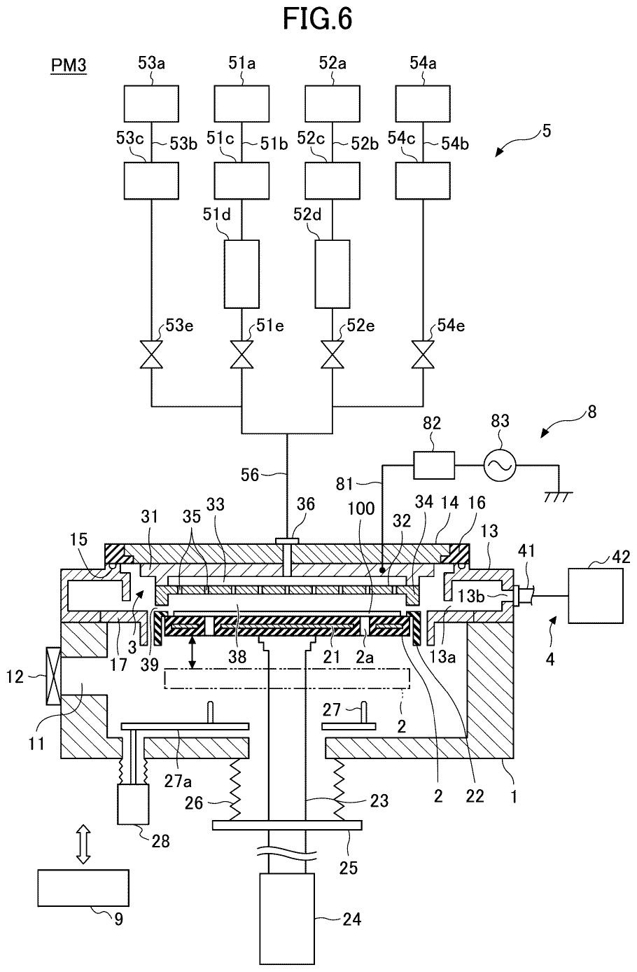

As will be described later, for example, a buffer tank 51d (see FIG. 6) is provided on a gas line 51b (see FIG. 6) for flowing the first metal-containing gas. It is preferable that step S13 includes alternately repeating buffering the first metal-containing gas in the buffer tank 51d provided on the gas line 51b and supplying the first metal-containing gas buffered in the buffer tank 51d a plurality of times. Performing the buffering the first metal-containing gas in the buffer tank 51d and supplying the first metal-containing gas buffered in the buffer tank 51d in this order may be hereinafter referred to as “fill flow of the first metal-containing gas”. The gas line 51b is an example of a “first gas line”. The buffer tank 51d is an example of a “first buffer tank”.

The number of times of fill flows of the first metal-containing gas is, for example, ten times or greater and a hundred times or less. The time for which to buffer the first metal-containing gas in the buffer tank 51d and the time for which to supply the first metal-containing gas buffered in the buffer tank 51d in one fill flow of the first metal-containing gas can be desirably set. In one fill flow of the first metal-containing gas, the time for which to buffer the first metal-containing gas in the buffer tank 51d and the time for which to supply the first metal-containing gas buffered in the buffer tank 51d may be the same or different. By performing the fill flow of the first metal-containing gas, it is possible to supply the first metal-containing gas having a high pressure and a high flow rate in one lump in a short time. That is, it is possible to expose the substrate 100 to the first metal-containing gas having a high pressure and a high flow rate, which is supplied intermittently. Thus, the amount of the adsorbed metal layer 140 on the doped region 121 can be increased as compared with a case of supplying the first metal-containing gas continuously. However, step S13 may include supplying the first metal-containing gas continuously without performing the fill flow of the first metal-containing gas. Step S13 may include continuously supplying the first metal-containing gas before and after the fill flow of the first metal-containing gas.

An example of the processing conditions of step S13 is as follows.
Flow rate of the first metal-containing gas: 10 sccm to 300 sccm
Processing pressure: 1 Torr to 9 Torr (133.3 Pa to 1,200 Pa)
Fill time (time for which to buffer gas): 0.01 seconds to 1 second

Step S14 is performed after step S13. As shown in FIG. 2D, step S14 includes supplying an n-type impurity-containing gas to form the diffusion-preventing layer 150 on the adsorbed metal layer 140. The n-type impurity-containing gas and the diffusion-preventing layer 150 contain an n-type impurity. N-type impurity-containing molecules in the n-type impurity-containing gas are adsorbed to the adsorbed metal layer 140, thereby forming the diffusion-preventing layer 150.

For example, the n-type impurity-containing molecules in the n-type impurity-containing gas react with the metal contained in the adsorbed metal layer 140 and adsorb to the adsorbed metal layer 140. That is, the n-type impurity-containing molecules in the n-type impurity-containing gas have a property of easily adsorbing to the adsorbed metal layer 140. Therefore, by forming the diffusion-preventing layer 150 on the adsorbed metal layer 140, it is possible to increase the amount of the diffusion-preventing layer 150 on the adsorbed metal layer 140 compared with a case of forming the diffusion-preventing layer 150 directly on the doped region 121. Therefore, the concentration of the n-type impurity contained in the diffusion-preventing layer 150 present between the substrate 100 and a first metal silicide film 160 described later can be improved. Thus, diffusion of the n-type impurity contained in the doped region 121 into the first metal silicide film 160 can be inhibited. As a result, decrease in the concentration of the n-type impurity in the doped region 121 can be inhibited, and increase in the contact resistance between the doped region 121 and the first metal silicide film 160 can be inhibited.

On the other hand, in a case of omitting step S13 to not form the adsorbed metal layer 140, the diffusion-preventing layer 150 has to be formed on the doped region 121. Here, the n-type impurity-containing molecules in the n-type impurity-containing gas are less easily adsorbed to the doped region 121 than to the adsorbed metal layer 140. Therefore, unless the temperature of the substrate 100 is increased to a relatively high temperature, a sufficient amount of the diffusion-preventing layer 150 may not be formed on the doped region 121. In this case, the concentration of the n-type impurity contained in the diffusion-preventing layer 150 might become low, which may make it impossible to sufficiently inhibit the diffusion of the n-type impurity from the doped region 121 to the first metal silicide film 160. However, if the temperature of the substrate 100 is increased, the substrate 100 may be deteriorated. In this regard, according to the present embodiment, forming the diffusion-preventing layer 150 on the adsorbed metal layer 140 enables forming a sufficient amount of the diffusion-preventing layer 150 without raising the temperature of the substrate 100 to a high temperature that may deteriorate the substrate 100. Thus, even though the temperature of the substrate 100 in step S14 is relatively low, the concentration of the n-type impurity to be contained in the diffusion-preventing layer 150 can be improved. As a result, the diffusion of the n-type impurity from the doped region 121 to the first metal silicide film 160 can be inhibited.

In step S14, it is preferable to maintain the temperature of the substrate 100 at 400° C. or higher and 480° C. or lower. By maintaining the temperature of the substrate 100 in step S14 at 400° C. or higher and 480° C. or lower, it is possible to avoid deteriorating the substrate 100, and to secure the diffusion-preventing layer 150 in a substantial amount on the adsorbed metal layer 140. That is, it is possible to avoid deterioration of the substrate 100, and to secure the n-type impurity to be contained in the diffusion-preventing layer 150 at a substantial concentration. However, the temperature of the substrate 100 in step S14 is not limited to 400° C. or higher and 480° C. or lower. The temperature of the substrate 100 in step S14 may be appropriately set depending on the types and the like of the n-type impurity-containing gas and the substrate 100.

The n-type impurity contained in the n-type impurity-containing gas is the same as the n-type impurity contained in the doped region 121. That is, when the n-type impurity contained in the doped region 121 is phosphorus, the n-type impurity contained in the n-type impurity-containing gas is phosphorus. When the n-type impurity contained in the doped region 121 is arsenic, the n-type impurity contained in the n-type impurity-containing gas is arsenic. When the n-type impurity contained in the doped region 121 is antimony, the n-type impurity contained in the n-type impurity-containing gas is antimony.

When the n-type impurity-containing gas contains phosphorus, the n-type impurity-containing gas contains, for example, phosphine (PH₃). When the n-type impurity-containing gas contains arsenic, the n-type impurity-containing gas contains, for example, arsine (AsH₃). When the n-type impurity-containing gas contains antimony, the n-type impurity-containing gas contains, for example, stibine (SbH₃).

Step S14 may include supplying a carrier gas together with the n-type impurity-containing gas. As in step S13, the carrier gas is, for example, an inert gas, such as nitrogen (N₂) gas, argon (Ar) gas, and the like.

In step S14, the n-type impurity-containing gas is supplied without being formed into a plasma. By supplying the n-type impurity-containing gas without forming it into a plasma, it is possible to avoid damage to the doped region 121 and the adsorbed metal layer 140 that might otherwise be caused by ions in a plasma. In addition, by supplying the n-type impurity-containing gas without forming it into a plasma, it is possible to form the diffusion-preventing layer 150 while preventing evaporation of the adsorbed metal layer 140 exposed to the n-type impurity-containing gas. In step S14, the n-type impurity-containing gas may be supplied in the form of a plasma. By supplying the n-type impurity-containing gas in the form of a plasma, it is possible to further facilitate adsorption of the n-type impurity to the doped region 121 and the adsorbed metal layer 140.

As will be described later, for example, a buffer tank 52d (see FIG. 6) is provided on a gas line 52b (see FIG. 6) for flowing the n-type impurity-containing gas. It is preferable that step S14 includes alternately repeating buffering the n-type impurity-containing gas in the buffer tank 52d provided on the gas line 52b and supplying the n-type impurity-containing gas buffered in the buffer tank 52d a plurality of times. Buffering the n-type impurity-containing gas in the buffer tank 52d and supplying the n-type impurity-containing gas buffered in the buffer tank 52d in this order may be hereinafter referred to as “fill flow of the n-type impurity-containing gas”. The gas line 52b is an example of a “second gas line”. The buffer tank 52d is an example of a “second buffer tank”.

The number of times of fill flows of the n-type impurity-containing gas is, for example, ten times or greater and three hundred times or less. In one fill flow of the n-type impurity-containing gas, the time for which to buffer the n-type impurity-containing gas in the buffer tank 52d and the time for which to supply the n-type impurity-containing gas buffered in the buffer tank 52d can be desirably set. The time for which to buffer the n-type impurity-containing gas in the buffer tank 52d and the time for which to supply the n-type impurity-containing gas buffered in the buffer tank 52d in one fill flow of the n-type impurity-containing gas may be the same or different. By performing the fill flow of the n-type impurity-containing gas, it is possible to supply the n-type impurity-containing gas having a high pressure and a high flow rate in one lump in a short time. That is, by performing the fill flow of the n-type impurity-containing gas, it is possible to expose the adsorbed metal layer 140 to the n-type impurity-containing gas having a high pressure and a high flow rate, which is supplied intermittently. Thus, the amount of the diffusion-preventing layer 150 can be increased as compared with a case of supplying the n-type impurity-containing gas continuously. However, step S14 may include supplying the n-type impurity-containing gas continuously without performing the fill flow of the n-type impurity-containing gas. Step S14 may also include supplying the n-type impurity-containing gas continuously before and after the fill flow of the n-type impurity-containing gas.

An example of the processing conditions of the step S14 is as follows.
Flow rate of the n-type impurity-containing gas: 100 sccm to 900 sccm
Processing pressure: 1 Torr to 100 Torr (133.3 Pa to 13,333.3 Pa)
Fill time (time for which to buffer gas): 0.1 seconds to 2 seconds

In the film formation method according to the first embodiment, steps S13 and S14 may be alternately repeated a plurality of times. Here, it is preferable to repeat performing the fill flow of the first metal-containing gas a plurality of times and subsequently performing the fill flow of the n-type impurity-containing gas a plurality of times. As a result, a sufficient amount of the diffusion-preventing layer 150 can be formed on a sufficient amount of the adsorbed metal layer 140, thereby better improving the concentration of the n-type impurity to be contained in the diffusion-preventing layer 150. As a result, the diffusion of the n-type impurity from the doped region 121 to the first metal silicide film 160 can be better inhibited. However, performing the fill flow of the first metal-containing gas a single time and subsequently performing the fill flow of the n-type impurity-containing gas a single time may be repeated. Further, also in a case of not performing the fill flow of the first metal-containing gas in step S13 and not performing the fill flow of the n-type impurity-containing gas in step S14 (that is, in a case of continuously supplying the first metal-containing gas and continuously supplying the n-type impurity-containing gas), supplying the first metal-containing gas and supplying the n-type impurity-containing gas may be alternately repeated a plurality of times.

Further, in the film formation method according to the first embodiment, step S13 and step S14 may be performed in the same processing vessel. By performing steps S13 and S14 in the same processing vessel, it is possible to avoid exposing the substrate 100 and the adsorbed metal layer 140 to the open air, and to shorten the processing time taken until the diffusion-preventing layer 150 is formed. When performing steps S13 and S14 in the same processing vessel, step S14 may be performed while maintaining the temperature of the substrate 100 in step S13. By performing step S14 while maintaining the temperature of the substrate 100 in step S13, it is possible to further shorten the processing time taken until the diffusion-preventing layer 150 is formed.

In the film formation method according to the first embodiment, the processing pressure in step S14 may be higher than the processing pressure in step S13. By setting the processing pressure in step S14 to a high pressure, it is possible to further facilitate adsorption of the n-type impurity, and hence formation of the diffusion-preventing layer 150 containing the n-type impurity. The processing pressure in step S14 may be, for example, in a range of 7 Torr or higher and 70 Torr or lower.

Step S15 is performed after step S14. As shown in FIG. 2E, step S15 includes supplying a second metal-containing gas to form a first metal film over the doped region 121 over which the diffusion-preventing layer 150 is formed, to form the first metal silicide film 160 through a reaction between the first metal film and silicon in the doped region 121.

The second metal-containing gas may be the same as or different from the first metal-containing gas. Examples of the second metal-containing gas include the gases listed as examples of the first metal-containing gas.

Step S15 may include supplying a reducing gas together with the second metal-containing gas. Step S15 may also include forming the first metal film over the doped region 121 by exposing the substrate 100 to a plasma of the second metal-containing gas and the reducing gas. Step S15 may also include forming the first metal film over the doped region 121 by alternately repeating a plurality of times, supplying the second metal-containing gas to the substrate 100 and supplying the reducing gas to the substrate 100 in the form of a plasma. Step S15 may also include forming the first metal film over the doped region 121 by simultaneously performing supplying the second metal-containing gas to the substrate 100 and supplying the reducing gas to the substrate 100 in the form of a plasma. The first metal film reacts with silicon in the doped region 121 to form the first metal silicide film 160. The reducing gas is, for example, hydrogen (H₂) gas. However, the reducing gas is not limited to hydrogen gas.

As described above, by performing step S13, it is possible to reduce the temperature of the substrate 100 when forming the diffusion-preventing layer 150 in step S14. Therefore, the temperature of the substrate 100 in step S14 can be set to be equal to or lower than the temperature of the substrate 100 in step S15, for example. By setting the temperature of the substrate 100 in step S14 to be equal to or lower than the temperature of the substrate 100 in step S15, it is possible to avoid deterioration of the substrate 100, and to inhibit increase in the contact resistance between the doped region 121 and the first metal silicide film 160.

In step S15, it is preferable to maintain the temperature of the substrate 100 at 400° C. or higher and 480° C. or lower. Moreover, in step S13, step S14, and step S15, it is preferable to maintain the temperature of the substrate 100 at 400° C. or higher and 480° C. or lower. In this way, it is possible to form the adsorbed metal layer 140, the diffusion-preventing layer 150, and the first metal silicide film 160, respectively, even by setting the temperature of the substrate 100 to a relatively low temperature at which the substrate 100 is lowly likely to be deteriorated. As a result, it is possible to avoid deterioration of the substrate 100, and to inhibit increase in the contact resistance between the doped region 121 and the first metal silicide film 160.

An example of the processing conditions in step S15 is as follows.
Flow rate of the second metal-containing gas: 10 sccm to 100 sccm
Flow rate of the reducing gas: 10 sccm to 5,000 sccm
Processing pressure: 1 Torr to 9 Torr (133.3 Pa to 1,200 Pa)
RF power: 150 W to 900 W
Processing Time: 10 Seconds to 180 Seconds

According to the film formation method described above, the adsorbed metal layer 140 as the adsorption-promoting layer and the diffusion-preventing layer 150 are sequentially formed over the doped region 121 before the first metal silicide film 160 is formed over the doped region 121. Since the diffusion-preventing layer 150 is formed on the adsorbed metal layer 140, the concentration of the n-type impurity contained in the diffusion-preventing layer 150 can be improved. As a result, when forming the first metal silicide film 160, the n-type impurity in the diffusion-preventing layer 150 can diffuse more easily into the first metal silicide film 160 than does the n-type impurity in the doped region 121. Therefore, the diffusion of the n-type impurity from the doped region 121 into the first metal silicide film 160 can be inhibited. As a result, the concentration of the n-type impurity contained in the doped region 121 can be inhibited from decreasing from the concentration before the first metal silicide film 160 is formed, and increase in the contact resistance between the doped region 121 and the first metal silicide film 160 can be inhibited.

### Film Formation Method According to Second Embodiment

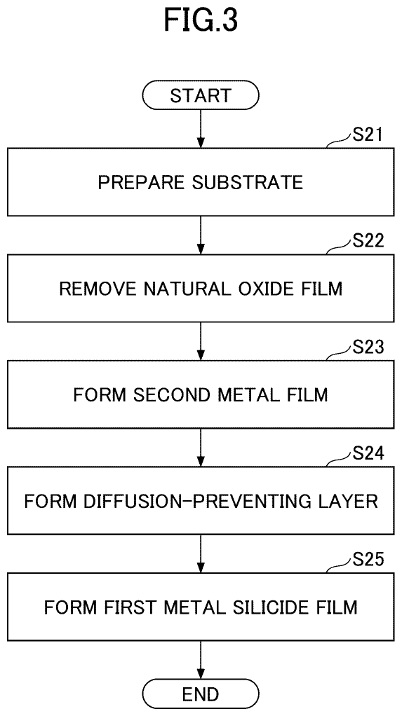

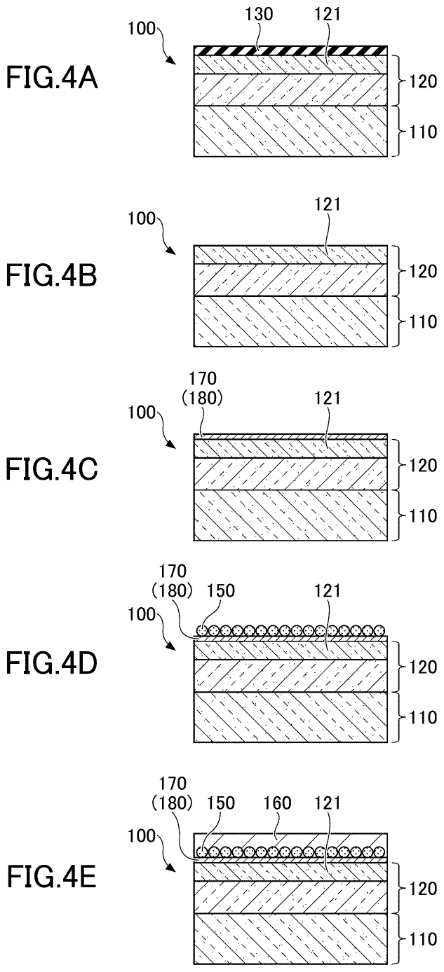

An example of a film formation method according to a second embodiment will be described with reference to FIGS. 3 and 4A to 4E. FIG. 3 is a flowchart showing an example of the film formation method according to the second embodiment. FIGS. 4A to 4E are cross-sectional views showing an example of the film formation method according to the second embodiment.

The film formation method according to the second embodiment includes forming a second metal film 170 as an adsorption-promoting layer before forming a diffusion-preventing layer 150. The film formation method according to the second embodiment includes steps S21 to S25 shown in FIG. 3. In the second embodiment, the adsorption-promoting layer may be a second metal silicide film 180 formed from the second metal film 170. The second metal silicide film 180 will be described separately.

Step S21 includes preparing a substrate 100 as shown in FIG. 4A. Step S21 may be the same as step S11.

Step S22 is performed after step S21. Step S22 includes removing a natural oxide film 130 present on the surface of a doped region 121 as shown in FIG. 4B. step S22 may be the same as step S12.

Step S23 is performed after step S22. As shown in FIG. 4C, step S23 includes forming the second metal film 170 as the adsorption-promoting layer on the doped region 121 by exposing the substrate 100 to a plasma formed from a first metal-containing gas and a reducing gas. The second metal film 170 promotes adsorption of an n-type impurity of the diffusion-preventing layer 150 containing the n-type impurity to be formed in step S24. Step S23 may include forming the second metal film 170 on the doped region 121 by alternately repeating supplying the first metal-containing gas to the substrate 100 and supplying the reducing gas to the substrate 100 in the form of a plasma. Step S23 may also include forming the second metal film 170 on the doped region 121 by simultaneously performing supplying the first metal-containing gas to the substrate 100 and supplying the reducing gas to the substrate 100 in the form of a plasma. The reducing gas is, for example, hydrogen (H₂) gas. Step S23 may also include maintaining the substrate 100 at, for example, 400° C. or higher and 480° C. or lower. Thus, it is possible to form the second metal silicide film 180 through a thermal reaction with silicon in the doped region 121, while forming the second metal film 170.

It is preferable that the second metal film 170 is a thin film from the viewpoint of adsorbing many n-type impurity-containing molecules near the doped region 121 to increase the concentration of the n-type impurity to be contained in the diffusion-preventing layer 150. The thickness of the second metal film 170 may be, for example, 1 nm or greater and 3 nm or less.

The first metal-containing gas used in step S23 may be the same as the first metal-containing gas used in step S13.

Step S23 may include supplying a carrier gas together with the first metal-containing gas. The carrier gas is, for example, an inert gas such as nitrogen (N₂) gas, argon (Ar) gas, and the like.

An example of the processing conditions of step S23 is as follows.
Flow rate of the first metal-containing gas: 10 sccm to 100 sccm
Flow rate of the reducing gas: 10 sccm to 5,000 sccm
Processing pressure: 1 Torr to 9 Torr (133.3 Pa to 1,200 Pa)
RF power: 150 W to 900 W
Processing time: 10 seconds to 60 seconds

For example, n-type impurity-containing molecules in an n-type impurity-containing gas react with the metal contained in the second metal film 170 (second metal silicide film 180) and adsorb to the second metal film 170 (second metal silicide film 180). That is, the n-type impurity-containing molecules in the n-type impurity-containing gas have a property of easily adsorbing to the second metal film 170 (second metal silicide film 180). Therefore, by forming the diffusion-preventing layer 150 on the second metal film 170 (second metal silicide film 180), it is possible to increase the amount of the diffusion-preventing layer 150 on the second metal film 170 (second metal silicide film 180) as compared with a case of forming the diffusion-preventing layer 150 directly on the doped region 121. Therefore, the concentration of the n-type impurity contained in the diffusion-preventing layer 150 present between the substrate 100 and a first metal silicide film 160 described later can be improved. As a result, diffusion of the n-type impurity contained in the doped region 121 into the first metal silicide film 160 can be inhibited. As a result, decrease in the concentration of the n-type impurity in the doped region 121 is inhibited, and increase in the contact resistance between the doped region 121 and the first metal silicide film 160 can be inhibited.

Step S24 is performed after step S23. As shown in FIG. 4D, step S24 includes supplying the n-type impurity-containing gas to form the diffusion-preventing layer 150 on the second metal film 170 (the second metal silicide film 180). Step S24 may be the same as Step S14.

Step S25 is performed after step S24. As shown in FIG. 4E, step S25 includes supplying a second metal-containing gas to form a first metal film over the doped region 121 over which the diffusion-preventing layer 150 is formed, to form the first metal silicide film 160 through a reaction between the first metal film and silicon in the doped region 121. Step S25 may be the same as step S15.

According to the film formation method according to the second embodiment described above, the second metal film 170 (second metal silicide film 180) as the adsorption-promoting layer and the diffusion-preventing layer 150 are sequentially formed on the doped region 121 before the first metal silicide film 160 is formed over the doped region 121. Since the diffusion-preventing layer 150 is formed on the second metal film 170 (second metal silicide film 180), the concentration of the n-type impurity contained in the diffusion-preventing layer 150 can be improved. Thus, when forming the first metal silicide film 160, the n-type impurity in the diffusion-preventing layer 150 can diffuse more easily into the first metal silicide film 160 than does the n-type impurity in the doped region 121. Therefore, the diffusion of the n-type impurity from the doped region 121 into the first metal silicide film 160 can be inhibited. As a result, the concentration of the n-type impurity contained in the doped region 121 can be inhibited from decreasing from the concentration before the first metal silicide film 160 is formed, and increase in the contact resistance between the doped region 121 and the first metal silicide film 160 can be inhibited.

### Processing System

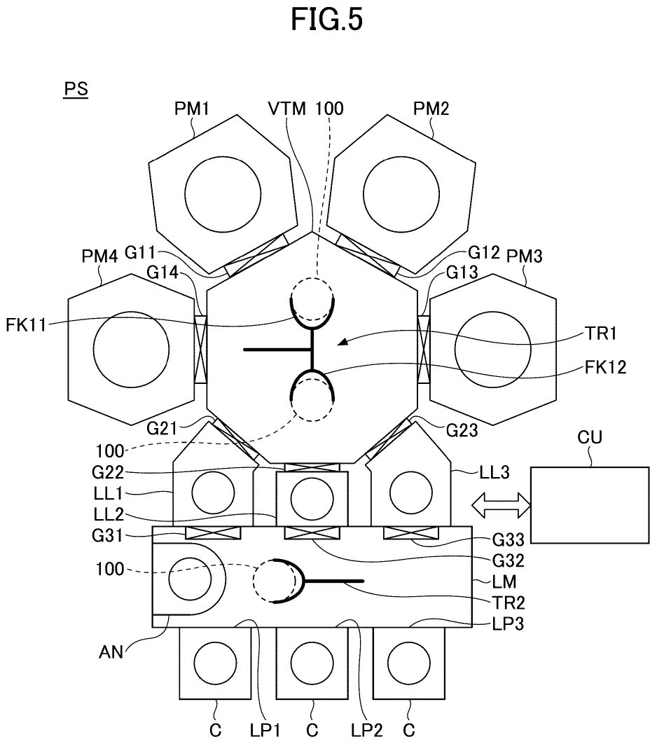

Referring to FIG. 5, an example of a processing system PS in which the film formation methods according to the embodiments can be implemented will be described. FIG. 5 is a diagram showing an example of the processing system PS according to an embodiment.

The processing system PS includes processing apparatuses PM1 to PM4, a vacuum conveying chamber VTM, load lock chambers LL1 to LL3, an open-air conveying chamber LM, load ports LP1 to LP3, and a total control unit CU.

The processing apparatuses PM1 to PM4 are connected to the vacuum conveying chamber VTM via gate valves G11 to G14, respectively. The interior of each of the processing apparatuses PM1 to PM4 is depressurized to a predetermined vacuum atmosphere. Each of the processing apparatuses PM1 to PM4 performs a desired process on the substrate 100 in the interior thereof. The processing apparatus PM1 is an apparatus for performing, for example, the COR treatment of step S12. The processing apparatus PM2 is an apparatus for performing, for example, the PHT of step S12. The processing apparatus PM3 is an apparatus for performing, for example, steps S13 and S14. However, steps S13 and S14 may be performed in different processing apparatuses. The processing apparatus PM4 is, for example, an apparatus for performing step S15.

The interior of the vacuum conveying chamber VTM is depressurized to a predetermined vacuum atmosphere. A conveying mechanism TR1 is provided in the interior of the vacuum conveying chamber VTM. The conveying mechanism TR1 is configured to convey the substrate 100 in a depressurized state. The conveying mechanism TR1 conveys the substrate 100 to the processing apparatuses PM1 to PM4 and to the load lock chambers LL1 to LL3. The conveying mechanism TR1 has, for example, two independently movable forks FK11 and FK12. The forks FK11 and FK12 are configured to hold substrates 100, respectively.

The load lock chambers LL1 to LL3 are connected to the vacuum conveying chamber VTM via gate valves G21 to G23, respectively. The load lock chambers LL1 to LL3 are connected to the open-air conveying chamber LM via gate valves G31 to G33, respectively. The interiors of the load lock chambers LL1 to LL3 are switchable between an open-air atmosphere and a vacuum atmosphere.

The open-air conveying chamber LM has an open-air atmosphere in the interior. In the open-air conveying chamber LM, for example, a downflow of clean air is formed in the interior. An aligner AN is provided inside the open-air conveying chamber LM. The aligner AN aligns the substrate 100. A conveying mechanism TR2 is provided in the open-air conveying chamber LM. The conveying mechanism TR2 conveys the substrate 100 to the load lock chambers LL1 to LL3, to carriers C at the load ports LP1 to LP3, and to the aligner AN.

The load ports LP1 to LP3 are provided on a wall surface of the open-air conveying chamber LM along a longer side of the open-air conveying chamber LM. Carriers C are attached to the load ports LP1 to LP3, respectively. The carriers C are, for example, Front Opening Unified Pods (FOUPs).

The total control unit CU is, for example, a computer. The total control unit CU includes a Central Processing Unit (CPU), a Random Access Memory (RAM), a Read Only Memory (ROM), and an auxiliary storage device. The CPU operates based on a program stored in the ROM or the auxiliary storage device, and controls each part of the processing system PS. For example, the total control unit CU executes operating the processing apparatuses PM1 to PM4, operating the conveying mechanisms TR1 and TR2, opening or closing the gate valves G11 to G14, G21 to G23, and G31 to G33, switching the atmospheres in the load lock chambers LL1 to LL3, and the like.

### Operation of Processing System

An example of the operation of the processing system PS according to the embodiment will be described with reference to FIG. 5. The operation of the processing system PS according to the embodiment is performed under the control by the total control unit CU. The total control unit CU is an example of a “controller”. The total control unit CU controls gas supplies provided to the processing apparatuses PM1 to PM4 to perform steps S11 to S15 of the film formation method according to the embodiment. The supplies are configured to supply the first metal-containing gas, the n-type impurity-containing gas, and the second metal-containing gas, respectively. In the example shown in FIG. 5, the supply provided to the processing apparatus PM3 (for example, a gas supply mechanism 5 shown in FIG. 6) is configured to supply the first metal-containing gas and the n-type impurity-containing gas. The supply provided to the processing apparatus PM4 is configured to supply the second metal-containing gas.

First, the carrier C in a state of storing a plurality of substrates 100 is attached to the load port LP1. Each of the substrates 100 may be a substrate 100 having a doped region 121 on a surface of the substrate 100.

Next, the conveying mechanism TR2 conveys the substrates 100 stored on the carrier C to the aligner AN. Next, the aligner AN aligns the substrates 100. Next, the total control unit CU switches the gate valve G31 in the closed state to the open state. Next, the conveying mechanism TR2 receives the substrates 100 from the aligner AN and conveys them to the load lock chamber LL1 in an open-air atmosphere. Next, the total control unit CU switches the gate valve G31 in the open state to the closed state. Next, the total control unit CU switches the interior in the load lock chamber LL1 from the open-air atmosphere to a vacuum atmosphere.

Next, the total control unit CU switches the gate valves G11 and G21 in the closed state to the open state. Next, the conveying mechanism TR1 receives the substrates 100 from the load lock chamber LL1 and loads a received substrate 100 into the processing vessel of the processing apparatus PM1. Next, the total control unit CU switches the gate valves G11 and G21 in the open state to the closed state.

Next, the processing apparatus PM1 performs the COR treatment of step S12. Thus, a surface layer of the natural oxide film 130 present on the surface of the doped region 121 formed on the surface of the substrate 100 is changed to a reaction product.

Next, the total control unit CU switches the gate valves G11 and G12 in the closed state to the open state. Next, the conveying mechanism TR1 receives the substrate 100 from the processing apparatus PM1 and conveys it to the processing apparatus PM2. Next, the total control unit CU switches the gate valves G11 and G12 in the open state to the closed state.

Next, the processing apparatus PM2 performs the PHT of step S12. As a result, the reaction product remaining on the surface of the substrate 100 are sublimated, and the natural oxide film 130 present on the surface of the doped region 121 is removed.

Next, the total control unit CU switches the gate valves G12 and G13 in the closed state to the open state. Next, the conveying mechanism TR1 receives the substrate 100 from the processing apparatus PM2 and conveys it to the processing apparatus PM3. Next, the total control unit CU switches the gate valves G12 and G13 in the open state to the closed state.

Next, the processing apparatus PM3 performs step S13. As a result, the adsorbed metal layer 140 is formed on the doped region 121. In a case where the processing apparatus PM3 performs step S23, the second metal film 170 (second metal silicide film 180) is formed on the doped region 121. Next, the processing apparatus PM3 performs step S14. As a result, a diffusion-preventing layer 150 is formed on the adsorbed metal layer 140. In a case where the processing apparatus PM3 performs step S24, the diffusion-preventing layer 150 is formed on the second metal silicide film 180.

Next, the total control unit CU switches the gate valves G13 and G14 in the closed state to the open state. Next, the conveying mechanism TR1 receives the substrate 100 from the processing apparatus PM3 and conveys it to the processing apparatus PM4. Next, the total control unit CU switches the gate valves G13 and G14 in the open state to the closed state.

Next, the processing apparatus PM4 performs steps S15 and S25. Thus, the first metal film is formed over the doped region 121 over which the diffusion-preventing layer 150 is formed. The first metal silicide film 160 is formed through reaction between the first metal film and silicon in the doped region 121.

Next, the total control unit CU switches the gate valves G14 and G23 in the closed state to the open state. Next, the conveying mechanism TR1 receives the substrate 100 from the processing apparatus PM4 and conveys it to the load lock chamber LL3 in a vacuum atmosphere. Next, the total control unit CU switches the gate valves G14 and G23 in the open state to the closed state. Next, the total control unit CU switches the interior of the load lock chamber LL3 from the vacuum atmosphere to the open-air atmosphere.

Next, the total control unit CU switches the gate valve G33 in the closed state to the open state. Next, the conveying mechanism TR2 receives the substrate 100 from the load lock chamber LL3, conveys it to the carrier C attached to the load port LP3, and accommodates the substrate 100 in the carrier C. Thus, the process for one substrate 100 is completed.

In the operation of the processing system PS described above, the case where the substrate 100 is conveyed from the open-air conveying chamber LM to the vacuum conveying chamber VTM via the load lock chamber LL1 and the substrate 100 is conveyed from the vacuum conveying chamber VTM to the open-air conveying chamber LM via the load lock chamber LL3 has been described. However, the path along which to convey the substrate 100 is not limited to this. The substrate 100 may be conveyed from the open-air conveying chamber LM to the vacuum conveying chamber VTM via any one of the load lock chambers LL1 to LL3. The substrate 100 may be conveyed from the vacuum conveying chamber VTM to the open-air conveying chamber LM via any one of the load lock chambers LL1 to LL3.

### Processing Apparatus

An example of the processing apparatus PM3 will be described with reference to FIG. 6. FIG. 6 is a diagram showing an example of the processing apparatus PM3. For example, the processing apparatus PM3 is configured to perform steps S13 and S14. Moreover, for example, the processing apparatus PM3 is configured to perform steps S23 and S24.

As shown in FIG. 6, the processing apparatus PM3 includes a processing vessel 1, a mounting table 2, a showerhead 3, a gas exhaust 4, a gas supply mechanism 5, an RF power supply 8, and a controller 9. The gas supply mechanism 5 is an example of a “supply”. For example, the controller 9 executes steps S13 and S14 by controlling the gas supply mechanism 5. Alternatively, for example, the controller 9 may execute steps S23 and S24 by controlling the gas supply mechanism 5.

The processing vessel 1 is composed of a metal, such as aluminum and the like, and has an approximately cylindrical shape. The processing vessel 1 is configured to accommodate a substrate 100 having a doped region 121 containing silicon and an n-type impurity on a surface of the substrate 100. A loading/unloading opening 11 for loading or unloading the substrate 100 is provided in a side wall of the processing vessel 1. The loading/unloading opening 11 is opened and closed by a gate valve 12. An annular gas exhaust duct 13 having a rectangular cross section is provided on the main body of the processing vessel 1. A slit 13a is formed in the gas exhaust duct 13 along the inner peripheral surface of the gas exhaust duct 13. A gas exhaust opening 13b is formed in an outer wall of the gas exhaust duct 13. A top wall 14 is provided on the upper surface of the gas exhaust duct 13 so as to close the upper opening of the processing vessel 1 via an insulator member 16. The space between the gas exhaust duct 13 and the insulator member 16 is airtightly sealed by a seal ring 15. A partitioning member 17 partitions the interior of the processing vessel 1 into an upper section and a lower section when the mounting table 2 and a cover member 22 are raised to a processing position described later.

The mounting table 2 horizontally supports the substrate 100 in the processing vessel 1. The mounting table 2 is formed in a disk shape slightly larger than the substrate 100. The mounting table 2 is composed of a ceramic material, such as AlN and the like, or a metal material, such as aluminum, nickel alloy, and the like. A heater 21 for heating the substrate 100 is embedded in the mounting table 2. The heater 21 is supplied with power from a heater power source (not shown) to generate heat. By controlling an output from the heater 21 based on a temperature signal from a thermocouple (not shown) provided near the upper surface of the mounting table 2, the substrate 100 is controlled to a predetermined temperature. The cover member 22 is provided on the mounting table 2 so as to cover the outer peripheral region of the upper surface of and the side surface of the mounting table 2. The cover member 22 is composed of ceramics, such as alumina and the like.

A support member 23 is connected to the bottom surface of the mounting table 2. The support member 23 supports the mounting table 2. The support member 23 extends from the center of the bottom surface of the mounting table 2 to under the processing vessel 1 through a hole formed in the bottom wall of the processing vessel 1, and the lower end of the support member 23 is connected to a lifting mechanism 24. The mounting table 2 is raised and lowered by the lifting mechanism 24 via the support member 23. The mounting table 2 is raised and lowered between the processing position indicated by a solid line in FIG. 6 and a conveying position indicated by a two-dot chain line below the processing position. The processing position is a position at which the substrate 100 is processed. The conveying position is a position at which the substrate 100 is loaded or unloaded. A flange 25 is attached to the support member 23 below the processing vessel 1. A bellows 26 is provided between the bottom surface of the processing vessel 1 and the flange 25. The bellows 26 partitions the atmosphere in the processing vessel 1 from the open air, and extends and contracts along with the operation for raising and lowering the mounting table 2.

Three (only two are shown) lifting pins 27 are provided near the bottom surface of the processing vessel 1. The lifting pins 27 project upward from a lifting plate 27a. The lifting pins 27 are raised and lowered via the lifting plate 27a by a lifting mechanism 28 provided under the processing vessel 1. The lifting pins 27 are inserted through through-holes 2a provided in the mounting table 2 at the conveying position, and can be projected from and retracted into the upper surface of the mounting table 2. By raising and lowering the lifting pins 27, the substrate 100 is delivered between a conveying mechanism (not shown) and the mounting table 2.

The showerhead 3 supplies a processing gas into the processing vessel 1 in the form of a shower. The showerhead 3 is composed of a metal. The showerhead 3 is provided so as to face the mounting table 2. The showerhead 3 has almost the same diameter as that of the mounting table 2. The showerhead 3 includes a body part 31 fixed to the top wall 14 of the processing vessel 1 and a shower plate 32 connected under the body part 31. A gas diffusion space 33 is formed between the body part 31 and the shower plate 32. A gas introduction hole 36 is provided to the gas diffusion space 33 so as to penetrate the center of the top wall 14 of the processing vessel 1 and the body part 31. An annular projection 34 projecting downward is formed along the periphery of the shower plate 32. A plurality of gas discharge holes 35 are formed in flat surfaces present on the inner side of the annular projection 34. When the mounting table 2 is present at the processing position, a processing space 38 is formed between the mounting table 2 and the shower plate 32, and the upper surface of the cover member 22 and the annular projection 34 are close to each other to form an annular gap 39.

The gas exhaust 4 exhausts the interior of the processing vessel 1. The gas exhaust 4 includes a gas exhaust pipe 41 and a gas exhaust mechanism 42. The gas exhaust pipe 41 is connected to the gas exhaust opening 13b. The gas exhaust mechanism 42 includes a vacuum pump, a pressure control valve, and the like connected to the gas exhaust pipe 41. In processing, the gas in the processing vessel 1 reaches the gas exhaust duct 13 through the slit 13a, and is exhausted from the gas exhaust duct 13 through the gas exhaust pipe 41 by means of the gas exhaust mechanism 42.

The gas supply mechanism 5 supplies a processing gas into the processing vessel 1. The gas supply mechanism 5 includes a supply source 51a of the first metal-containing gas, a supply source 52a of the n-type impurity-containing gas, a supply source 53a of the carrier gas to be supplied together with the first metal-containing gas, and a supply source 54a of the carrier gas to be supplied together with the n-type impurity-containing gas. In a case of supplying no carrier gas, the supply sources 53a and 54a can be omitted.

The supply source 51a supplies the first metal-containing gas into the processing vessel 1 via the gas line 51b. The first metal-containing gas is used for forming the adsorbed metal layer 140. The first metal-containing gas may also be used for forming the second metal film 170. In the present embodiment, the first metal-containing gas includes titanium tetrachloride gas. The gas line 51b is provided with a flow rate controller 51c, the buffer tank 51d, and a valve 51e from the upstream side. A part of the gas line 51b downstream of the valve 51e is connected to the gas introduction hole 36 through a gas line 56. The first metal-containing gas supplied from the supply source 51a is temporarily stored in the buffer tank 51d before being supplied into the processing vessel 1, and after being increased to a predetermined pressure in the buffer tank 51d, is supplied into the processing vessel 1. The supply and stoppage of the first metal-containing gas from the buffer tank 51d into the processing vessel 1 are performed by opening and closing the valve 51e. By temporarily storing the first metal-containing gas in the buffer tank 51d, it is possible to supply the first metal-containing gas having a high pressure and a high flow rate stably into the processing vessel 1. However, the buffer tank 51d does not need to be provided on the gas line 51b. In this case, for example, the first metal-containing gas flowing through the gas line 51b is continuously supplied into the processing vessel 1 with the flow rate of the first metal-containing gas controlled by the flow rate controller 51c.

The supply source 52a supplies the n-type impurity-containing gas into the processing vessel 1 via the gas line 52b. The n-type impurity-containing gas is used for forming the diffusion-preventing layer 150. In the present embodiment, the n-type impurity-containing gas contains phosphine. The gas line 52b is provided with a flow rate controller 52c, the buffer tank 52d, and a valve 52e from the upstream side. A part of the gas line 52b downstream of the valve 52e is connected to the gas introduction hole 36 through the gas line 56. The n-type impurity-containing gas supplied from the supply source 52a is temporarily stored in the buffer tank 52d before being supplied into the processing vessel 1, and after being increased to a predetermined pressure in the buffer tank 52d, is supplied into the processing vessel 1. The supply and stoppage of the n-type impurity-containing gas from the buffer tank 52d into the processing vessel 1 are performed by opening and closing the valve 52e. By temporarily storing the n-type impurity-containing gas in the buffer tank 52d, it is possible to supply the n-type impurity-containing gas having a high pressure and a high flow rate stably into the processing vessel 1. However, the buffer tank 52d does not need to be provided on the gas line 52b. In this case, for example, the n-type impurity-containing gas flowing through the gas line 52b is continuously supplied into the processing vessel 1 with the flow rate of the n-type impurity-containing gas controlled by the flow rate controller 52c.

The supply source 53a supplies an inert gas, such as nitrogen gas, argon gas, and the like, into the processing vessel 1 through a gas line 53b. The gas line 53b is provided with a flow rate controller 53c and a valve 53e from the upstream side. A part of the gas line 53b downstream of the valve 53e is connected to the gas line 51b. The inert gas supplied from the supply source 53a is supplied into the processing vessel 1. The supply and stoppage of the inert gas into the processing vessel 1 are performed by opening and closing the valve 53e.

The supply source 54a supplies an inert gas, such as nitrogen gas, argon gas, and the like, into the processing vessel 1 via a gas line 54b. The gas line 54b is provided with a flow rate controller 54c and a valve 54e from the upstream side. A part of the gas line 54b downstream of the valve 54e is connected to the gas line 52b. The inert gas supplied from the supply source 54a is supplied into the processing vessel 1. The supply and stoppage of the inert gas into the processing vessel 1 is performed by opening and closing the valve 54e.

The processing apparatus PM3 is a capacitively coupled plasma apparatus in which the mounting table 2 serves as a lower electrode and the showerhead 3 serves as an upper electrode. The mounting table 2 serving as the lower electrode is grounded via a capacitor (not shown). However, in a case of forming no plasma of the first metal-containing gas and the n-type impurity-containing gas, the components functioning as the capacitively coupled plasma apparatus are not used.

An RF power is applied to the showerhead 3 serving as the upper electrode by the RF power supply 8. The RF power supply 8 includes a power supply line 81, a matcher 82, and a high-frequency power source 83. The high-frequency power source 83 is a power source for generating a high-frequency power. The high-frequency power has a frequency suitable for forming a plasma. The frequency of the high-frequency power is, for example, a frequency within a range of 450 KHz to 100 MHz. The high-frequency power source 83 is connected to the body part 31 of the showerhead 3 via the matcher 82 and the power supply line 81. The matcher 82 includes a circuit for matching the output reactance of the high-frequency power source 83 with the reactance of the load (upper electrode). Although the RF power supply 8 has been described as being configured to apply a high-frequency power to the showerhead 3 serving as the upper electrode, this is non-limiting. The RF power supply 8 may be configured to apply a high-frequency power to the mounting table 2 serving as the lower electrode.

The controller 9 is, for example, a computer. The controller 9 includes a CPU (Central Processing Unit), a RAM (Random Access Memory), a ROM (Read Only Memory), an auxiliary storage device, and the like. The CPU operates based on a program stored in the ROM or the auxiliary storage device, and controls the operation of the processing apparatus PM3. The controller 9 may be provided inside or outside the processing apparatus PM3. When the controller 9 is provided outside the processing apparatus PM3, the controller 9 controls the processing apparatus PM3 via a wired, wireless, or other communication method.

### Operation of Processing Apparatus

Referring to FIG. 6, as an example of the operation of the processing apparatus PM3, a case where the processing apparatus PM3 performs step S13 will be described. The substrate 100 may be a substrate 100 having a doped region 121 on a surface of the substrate 100. However, the same applies to a case where the processing apparatus PM3 performs step S23.

First, the controller 9 opens the gate valve 12, loads the substrate 100 into the processing vessel 1 by a conveying mechanism (not shown), and places the substrate on the mounting table 2. After retreating the conveying mechanism from the processing vessel 1, the controller 9 closes the gate valve 12. Next, the controller 9 heats the substrate 100 to a predetermined temperature by the heater 21 of the mounting table 2, and adjusts the pressure in the processing vessel 1 to a predetermined pressure by the gas exhaust mechanism 42. The predetermined temperature and the predetermined pressure may be the temperature and the pressure for performing step S13.

Next, the controller 9 executes step S13 by controlling each part of the processing apparatus PM3 including the gas supply mechanism 5. Specifically, the controller 9 switches the valve 51e in the closed state to the open state. Thus, the first metal-containing gas is supplied to the substrate 100, and the adsorbed metal layer 140 is formed on the doped region 121. After a predetermined time has elapsed, the controller 9 switches the valve 52e in the open state to the closed state.

The operation when the processing apparatus PM3 performs step S14 may be the same as the operation when the processing apparatus PM3 performs step S13, except that the adsorbed metal layer 140 has been formed on the substrate 100 and the valve to be controlled by the controller 9 is the valve 52e.

After step S13 and step S14 have been performed, the controller 9 unloads the substrate 100 from the processing vessel 1 by a procedure reversed from when loading the substrate 100 into the processing vessel 1. Thus, the processing on 1 substrate 100 is completed.

### Evaluation 1

Next, the film formation method according to the first embodiment will be described in more detail by using Example 1 and Comparative Examples 1 and 2 as Evaluation 1. However, the scope of the present disclosure is not limited to the following examples.

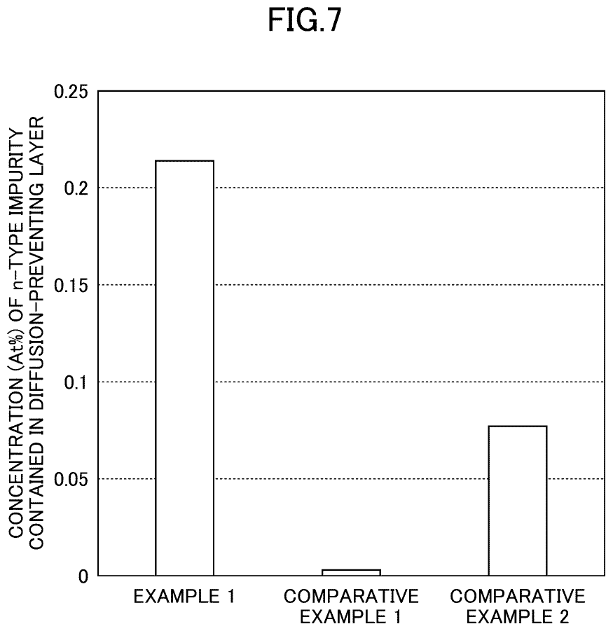

Measurement using X-ray Photoelectron Spectroscopy (XPS) was performed for Example 1 and Comparative Examples 1 and 2 to confirm the difference in the concentration of the n-type impurity contained in the diffusion-preventing layer 150. The measurement results of the concentration of the n-type impurity contained in the diffusion-preventing layer 150 will be described with reference to FIG. 7. The values shown on the vertical axis of FIG. 7 are the concentrations [at %] of the n-type impurity (for example, phosphorus) contained in the diffusion-preventing layer 150 in Example 1 and Comparative Examples 1 and 2. Hereinafter, the concentration of the n-type impurity contained in the diffusion-preventing layer 150 in Example 1 will be referred to as “n-type impurity concentration in Example 1”. The concentration of the n-type impurity contained in the diffusion-preventing layer 150 in Comparative Example 1 will be referred to as “n-type impurity concentration in Comparative Example 1”. The concentration of the n-type impurity contained in the diffusion-preventing layer 150 in Comparative Example 2 will be referred to as “n-type impurity concentration in Comparative Example 2”.

Example 1 is an example including an adsorbed metal layer 140 formed by performing step S13 and a diffusion-preventing layer 150 formed by performing step S14. In Example 1, a gas containing titanium tetrachloride was supplied as the first metal-containing gas to form the adsorbed metal layer 140. Further, for forming the adsorbed metal layer 140 of Example 1, fill flows of the first metal-containing gas were performed a plurality of times. In Example 1, a gas containing phosphine was supplied as the n-type impurity-containing gas to form the diffusion-preventing layer 150. Further, for forming the diffusion-preventing layer 150 of Example 1, fill flows of the n-type impurity-containing gas were performed a plurality of times. In Example 1, the temperature of the substrate 100 was set to 450° C. during the period in which step S13 to step S15 were performed.

Comparative Example 1 is an example including the diffusion-preventing layer 150 formed by performing Step S14 while omitting step S13. That is, Comparative Example 1 does not include the adsorbed metal layer 140. In Comparative Example 1, the diffusion-preventing layer 150 was formed by supplying a gas containing phosphine as the n-type impurity-containing gas. For forming the diffusion-preventing layer 150 of Comparative Example 1, the n-type impurity-containing gas was continuously supplied. In Comparative Example 1, the temperature of the substrate 100 was set to 450° C. during the period in which steps S14 and S15 were performed. In Comparative Example 1, the total flow rate of the n-type impurity-containing gas during the period in which step S14 was performed was set to be higher than the total flow rate of the n-type impurity-containing gas during the period in which step S14 was performed in Example 1.

Comparative Example 2 is an example including the diffusion-preventing layer 150 formed by performing step S14 while omitting step S13. That is, Comparative Example 2 does not include the adsorbed metal layer 140 as in Comparative Example 1. In Comparative Example 2, a gas containing phosphine was supplied as the n-type impurity-containing gas to form the diffusion-preventing layer 150. For forming the diffusion-preventing layer 150 of Comparative Example 2, fill flows of the n-type impurity-containing gas were performed a plurality of times. In Comparative Example 2, the temperature of the substrate 100 was set to 450° C. during the period in which steps S14 and S15 were performed. In Comparative Example 2, the flow rate of the n-type impurity-containing gas during the period in which step S14 was performed was set to be the same as the flow rate of the n-type impurity-containing gas during the period in which step S14 was performed in Example 1.

Processing conditions other than those described above were the same among Example 1 and Comparative Examples 1 and 2.

As shown in FIG. 7, the n-type impurity concentration in Example 1 was approximately 0.21 at %. In contrast, the n-type impurity concentration in Comparative Example 1 was approximately 0.003 at %. Although the total flow rate of the n-type impurity-containing gas in Example 1 was lower than the total flow rate of the n-type impurity-containing gas in Comparative Example 1, the n-type impurity concentration in Example 1 was improved to be approximately 70 times the n-type impurity concentration in Comparative Example 1. The n-type impurity concentration in Comparative Example 2 was approximately 0.08 at %. That is, the n-type impurity concentration in Example 1 was improved to be approximately 2.6 times the n-type impurity concentration in Comparative Example 2. From these results, it was confirmed that the concentration of the n-type impurity contained in the diffusion-preventing layer 150 was greatly improved by forming the diffusion-preventing layer 150 on the adsorbed metal layer 140 after forming the adsorbed metal layer 140.

As shown in FIG. 7, although the total flow rate of the n-type impurity-containing gas in Comparative Example 2 was lower than the total flow rate of the n-type impurity-containing gas in Comparative Example 1, the n-type impurity concentration in Comparative Example 2 was improved to be approximately 27 times the n-type impurity concentration in Comparative Example 1. From this result, it was confirmed that when the diffusion-preventing layer 150 was formed by performing the fill flow of the n-type impurity-containing gas, the concentration of the n-type impurity contained in the diffusion-preventing layer 150 was improved, compared to when the diffusion-preventing layer 150 was formed by continuously supplying the n-type impurity-containing gas. That is, it was confirmed that performing the fill flow of the n-type impurity-containing gas was effective from the viewpoint of improving the concentration of the n-type impurity contained in the diffusion-preventing layer 150.

### Evaluation 2

Next, the film formation method according to the second embodiment will be described in more detail by using Example 2, Example 3, and Comparative Example 3 as Evaluation 2. However, the scope of the present disclosure is not limited to the following examples.

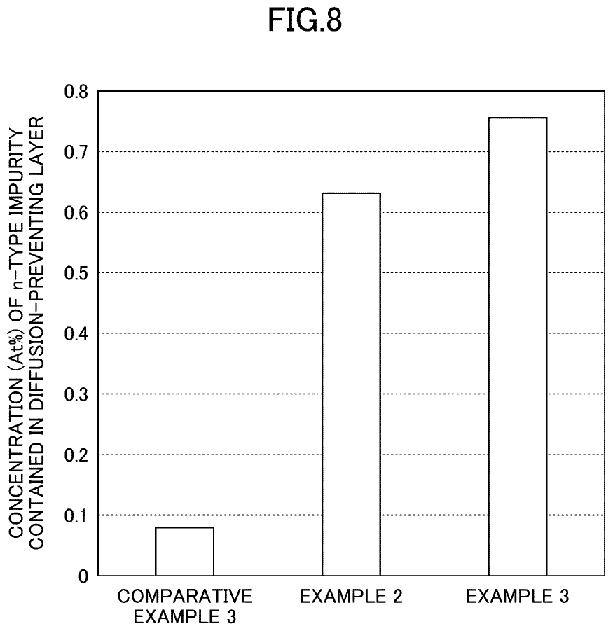

Measurement using X-ray Photoelectron Spectroscopy (XPS) was performed for Example 2, Example 3, and Comparative Example 3 to confirm the difference in the concentration of the n-type impurity contained in the diffusion-preventing layer 150. The measurement results of the concentration of the n-type impurity contained in the diffusion-preventing layer 150 will be described with reference to FIG. 8. In FIG. 8, the values shown on the vertical axis are the concentrations [at %] of the n-type impurity (for example, phosphorus) contained in the diffusion-preventing layer 150 in Example 2, Example 3, and Comparative Example 3. Hereinafter, the concentration of the n-type impurity contained in the diffusion-preventing layer 150 in Example 2 will be referred to as “n-type impurity concentration in Example 2”. The concentration of the n-type impurity contained in the diffusion-preventing layer 150 in Example 3 will be referred to as “n-type impurity concentration in Example 3”. The concentration of the n-type impurity contained in the diffusion-preventing layer 150 in Comparative Example 3 will be referred to as “n-type impurity concentration in Comparative Example 3”.

Examples 2 and 3 are examples including a second metal film 170 (second metal silicide film 180) formed by performing step S23 and a diffusion-preventing layer 150 formed by performing step S24. The difference between Examples 2 and 3 is only that the processing times for forming the second metal film 170 and the first metal film in steps S23 and S25 were varied, and other conditions were the same. In Examples 2 and 3, the second metal film 170 (second metal silicide film 180) was formed by exposing the substrate 100 to a plasma formed from a first metal-containing gas and a reducing gas. In Examples 2 and 3, the diffusion-preventing layer 150 was formed by supplying a gas containing phosphine as the n-type impurity-containing gas. For forming the diffusion-preventing layer 150 in Examples 2 and 3, fill flows of the n-type impurity-containing gas was performed a plurality of times. In Examples 2 and 3, the temperature of the substrate 100 was set to 450° C. during the period in which step S23 to step S25 were performed.

Comparative Example 3 is an example including the diffusion-preventing layer 150 formed by performing step S24 while omitting step S23. That is, Comparative Example 3 does not include the second metal film 170 (the second metal silicide film 180). In Comparative Example 3, the diffusion-preventing layer 150 was formed by supplying a gas containing phosphine as the n-type impurity-containing gas. In addition, for forming the diffusion-preventing layer 150 of Comparative Example 3, fill flows of the n-type impurity-containing gas were performed a plurality of times. In Comparative Example 3, the temperature of the substrate 100 was set to 450° C. during the period in which steps S24 and S25 were performed.

As shown in FIG. 8, the n-type impurity concentrations in Examples 2 and 3 were approximately 0.62 at % and approximately 0.75 at %, respectively. On the other hand, the n-type impurity concentration in Comparative Example 3 was approximately 0.08 at %. The n-type impurity concentrations in Examples 2 and 3 were improved o be approximately 7.8 times and approximately 9.4 times the n-type impurity concentration in Comparative Example 3, respectively. From these results, it was confirmed that the concentration of the n-type impurity contained in the diffusion-preventing layer 150 was greatly improved by forming the diffusion-preventing layer 150 on the second metal film 170 (second metal silicide film 180) after forming the second metal film 170 (second metal silicide film 180).

### Evaluation 3

Next, the processing pressure in step S14 (Step S24) and the adsorption amount of the n-type impurity will be described as Evaluation 3.

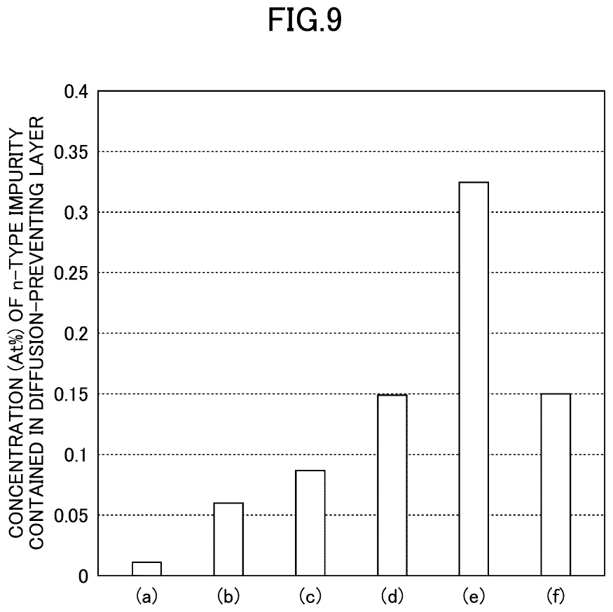

FIG. 9 shows the results of changing the supply amount of argon while maintaining the supply amount of phosphine constant, in a case of using phosphine (PH₃) as the n-type impurity and using argon (Ar) as the dilution gas (carrier gas) in step S14 (step S24). Here, the adsorption amount of the n-type impurity in the case of forming the diffusion-preventing layer 150 at the processing pressures of (a) 9 Torr, (b) 15 Torr, (c) 33 Torr, (d) 44 Torr, (e) 66 Torr, and (f) 88 Torr, respectively was measured using X-ray Photoelectron Spectroscopy (XPS), to confirm the difference in the concentration of the n-type impurity contained in the diffusion-preventing layer 150.

As shown in FIG. 9 at (a) to (e), it was confirmed that the concentration of the n-type impurity contained in the diffusion-preventing layer 150 increased as the processing pressure was increased by increasing the supply amount of argon. From these results, it was confirmed that the concentration of the n-type impurity contained in the diffusion-preventing layer 150 was greatly improved by increasing the processing pressure by increasing the supply amount of the dilution gas (inert gas), while maintaining the supply amount of the n-type impurity-containing gas constant. However, it was confirmed that the concentration of the n-type impurity contained in the diffusion-preventing layer 150 became low even at a high-pressure condition when the dilution by increasing the supply amount of the inert gas was excessive (case (f)). Therefore, the processing pressure in step S14 (step S24) is preferably from 9 Torr or higher and 66 Torr or lower. When including error, the processing pressure in step S14 (step S24) is preferably 7 Torr or higher and 70 Torr or lower.

It should be considered that the embodiments disclosed herein are exemplary and non-limiting in all respects. Various omissions, replacements, and modifications are applicable to the foregoing embodiments without departing from the scope and the spirit of the appended claims.

According to the present disclosure, it is possible to improve the concentration of an n-type impurity contained in a diffusion-preventing layer present between a substrate and a metal silicide film.

What is claimed is:

1. A film formation method, comprising:
(a) preparing a substrate having a doped region containing silicon and an n-type impurity on a surface of the substrate;
(b) supplying a first metal-containing gas to form an adsorption-promoting layer on the doped region;
(c) supplying an n-type impurity-containing gas containing the n-type impurity to form a diffusion-preventing layer containing the n-type impurity on the adsorption-promoting layer; and
(d) supplying a second metal-containing gas to form a first metal film over the doped region over which the diffusion-preventing layer is formed, and to form a first metal silicide film through a reaction between the first metal film and the silicon in the doped region.

2. The film formation method according to claim 1,
wherein a temperature of the substrate in the (c) is set to be equal to or lower than a temperature of the substrate in the (d).

3. The film formation method according to claim 1,
wherein in the (b), the (c), and the (d), a temperature of the substrate is maintained at 400° C. or higher and 450° C. or lower.

4. The film formation method according to claim 1,
wherein the (b) includes forming an adsorbed metal layer as the adsorption-promoting layer.

5. The film formation method according to claim 4,
wherein the (b) includes alternately repeating buffering the first metal-containing gas in a first buffer tank provided on a first gas line configured to flow the first metal-containing gas, and supplying the first metal-containing gas buffered in the first buffer tank a plurality of times.

6. The film formation method according to claim 5,
wherein in the (b), the first metal-containing gas is supplied without being formed into a plasma.

7. The film formation method according to claim 1,
wherein the (b) includes forming a second metal film as the adsorption-promoting layer.

8. The film formation method according to claim 7,
wherein the (b) includes forming the second metal film on the doped region by exposing the substrate to a plasma formed from the first metal-containing gas and a reducing gas.

9. The film formation method according to claim 8,
wherein a thickness of the second metal film formed in the (b) is 1 nm or greater and 3 nm or less.

10. The film formation method according to claim 1,
wherein the (c) includes alternately repeating buffering the n-type impurity-containing gas in a second buffer tank provided on a second gas line configured to flow the n-type impurity-containing gas, and supplying the n-type impurity-containing gas buffered in the second buffer tank a plurality of times.

11. The film formation method according to claim 10,
wherein in the (c), the n-type impurity-containing gas is supplied without being formed into a plasma.

12. The film formation method according to claim 10,
wherein a processing pressure in the (c) is higher than a processing pressure in the (b).

13. The film formation method according to claim 12,
wherein the processing pressure in the (c) is 7 Torr or higher and Torr or lower.

14. The film formation method according to claim 1, further comprising:
(e) alternately repeating the (b) and the (c) a plurality of times.

15. The film formation method according to claim 1,
wherein the (b) and the (c) are performed in a same processing vessel.

16. The film formation method according to claim 1, further comprising before the (b):
(f) removing a natural oxide film present on a surface of the doped region.

17. The film formation method according to claim 1,
wherein the first metal-containing gas contains titanium tetrachloride.

18. The film formation method according to claim 1,
wherein the n-type impurity is phosphorus, and
the n-type impurity-containing gas contains phosphine.

19. A processing system, comprising:
a processing vessel configured to accommodate a substrate having a doped region containing silicon and an n-type impurity on a surface of the substrate;
a supply configured to supply a gas into the processing vessel; and
a controller including a processor and a memory;
wherein the supply is configured to supply a first metal-containing gas, an n-type impurity-containing gas containing the n-type impurity, and a second metal-containing gas, and
by controlling the supply, the controller is configured to perform:
supplying the first metal-containing gas to form an adsorption-promoting layer on the doped region;
supplying the n-type impurity-containing gas to form a diffusion-preventing layer containing the n-type impurity on the adsorption-promoting layer; and
supplying the second metal-containing gas to form a first metal film over the doped region over which the diffusion-preventing layer is formed, and to form a first metal silicide film through a reaction between the first metal film and the silicon in the doped region.
